(19) United States
(12) Patent Application Publication
(10) Pub. No.: US 2012/0187526 A1
(43) Pub. Date: Jul. 26, 2012

(54) METHOD OF FORMING A SEMICONDUCTOR DEVICE TERMINATION AND STRUCTURE THEREFOR

(76) Inventors: Jaume Roig-Guitart, Oudenaarde (BE); Zia Hossain, Tempe, AZ (US); Peter Moens, Zottegem (BE)

(21) Appl. No.: 13/011,590

(22) Filed: Jan. 21, 2011

(51) Int. Cl. H01L 23/58; H01L 21/761

(52) U.S. Cl. 257/509; 438/400; 257/E23.002; 257/E21.544

(57) ABSTRACT

At least one exemplary embodiment is directed to a semiconductor edge termination structure, where the edge termination structure comprises several conductivity layers and a buffer layer.

### FIELD OF THE INVENTION

The present invention relates in general, to electronics, and more particularly though not exclusively, to semiconductors, structures thereof, and methods of forming semiconductor devices.

### BACKGROUND OF THE INVENTION

Semiconductor power switching devices can take several forms with two of the most common being Junction field-effect transistors (JFETs) and Metal-oxide semiconductor field effect transistors (MOSFETs). A JFET is a three-lead (gate, source, drain) semiconductor device that is exclusively voltage (no biasing current) controlled, that controls current flow between a drain and a source. A JFET is normally on when there is no voltage difference between its gate and source leads (i.e. the conductivity is at its highest) and increases in resistance when a voltage is applied across its gate. One can control the resistance by either a positive gate voltage (p-channel JFET) or a negative gate voltage (n-channel JFET). In an n-channel JFET when the gate voltage is negative relative to the source the area between two p-type semiconductor form two-reversed-biased junctions forming a depletion region hindering electron flow.

A MOSFET device is similar to a JFET including a source region, a drain region, a channel region extending between the source and drain regions, and a gate structure provided adjacent to the channel region. The MOSFET however also includes a gate structure that includes a conductive gate electrode layer disposed adjacent to and separated from the channel region by a thin dielectric layer. The addition of the thin dielectric layer (e.g., oxide) increases the gate lead input impedance, resulting in MOSFETs drawing substantially lower gate current compared to an equivalent JFET. The increased impedance however results in a low gate to channel capacitance such that if too high of an electric field is applied any accumulated charge may break from the gate to the channel damaging the MOSFET. Thus electric static discharge which can be thousands of volts can ruin a MOSFET device.

There are essentially two types of MOSFETs, and enhancement type MOSFET and a depletion type MOSFET. A depletion type MOSFET is normally on (maximum current flows from drain to source) when there is no voltage difference between the gate and source terminals, while an enhancement type MOSFET is normally off (minimal current flow from drain to source) when there is no voltage difference between the gate and source terminals. When a MOSFET device is in the on state, a voltage is applied to the gate structure to form a conduction channel region between the source and drain regions, which allows current to flow through the device. In the off state, any voltage applied to the gate structure is sufficiently low so that a conduction channel does not form, and thus current flow does not occur. During the off state, the device can support a high voltage between the source and drain regions.

Today's high voltage power switch market is driven by two major parameters: breakdown voltage (BV) and on-state resistance (RS). For a specific application, a high breakdown voltage is required, and in practice, designers typically can meet a BV specification. However, this is often at the expense of high RS. This trade-off in performance is a major design challenge for manufacturers and users of high voltage power switching devices. The maximum blocking voltage of a power MOSFET is limited by the edge termination that surrounds the semiconductor device active cell structures. Common edge termination structures are based upon floating rings and field plates, where the edge electric fields limits the breakdown voltage to about 80% of the parallel-plane breakdown voltage.

Recently, superjunction (Global Charge Balance, GCB termination) devices have gained in popularity to improve the trade-off between RS and BV. In a conventional n-channel superjunction device, multiple heavily-doped diffused n-type and p-type regions replace one lightly doped n-type epitaxial region. In the on state, current flows through the heavily doped N-type regions, which lowers RS. In the off or blocking state, the heavily doped N-type and P-type regions deplete into or compensate each other to provide a high BV. Many devices based on GCB termination exhibit a termination 100 that implements the same P (120) and N (130) pillars of the basic cell (same depth or shorter). This type of termination 100, schematically represented in FIG. 1, have the P (120) and N (130) pillars floating thus allowing a fully or partially depletion of these pillars. The termination layer ends in an N-channel stopper region 140 which is connected electrically via an N+ contact region 111 to the drain via a conductive electrode. The N and P pillars deposited on an N+ drain contact region 110. Typical GCB based semiconductor devices have termination 100 lengths >200 μm. The termination area takes away from the region of a semiconductor that can be used in the active device region. Hence if the termination region can be reduced while maintaining a low electric field at the edge, the semiconductor device can be reduced in size.

Another method of termination 200 is referred to as a Local Charge Balance (LCB) method. The LCB method utilizes a wide oxide trench 260 adjacent to N (220) and floating P (230) pillars in a lightly doped epitaxial layer 210 deposited on an N+ drain contact region 250. The LCB method includes the lightly doped epitaxial layer 210, which the GCB method replaced with N and P doped pillars. The lowly doped epitaxial layer 210 (<1×10¹⁴ cm⁻³) in “Local Charge Balance” devices, allows fast depletion and BV. However, the depletion region reaches the die edge when the termination length is reduced. Conventional systems additional use multi ring termination structures (e.g., 435, 437, and 439). In multi ring termination structures the depletion spreads slowing as each ring depletes, requiring 6 to 12 rings of long termination length to achieve the desired BV. Thus an LCB approach with current termination structures exhibits large area while protecting the edge of the die (with regards to electric field), while LCB+the termination illustrated in FIG. 2 reduces the area but the die edge is not safe (high electric fields).

In the related art system illustrated in FIG. 2, the depletion spreads very fast in the N− region 210 and most of the voltage is blocked by the wide oxide trench region, 260, resulting in long termination length and hence a large termination area. Moreover filing the trench with oxide may pose process challenges, and stress-induced defects.

Accordingly, an edge termination structure is needed that has a reduced termination area while minimizing E-field line termination at the edge of the die edge. Additionally, an edge termination structure is needed that provide lower RS, and a high BV.

### BRIEF DESCRIPTION OF THE DRAWINGS

Exemplary embodiments of present invention will become more fully understood from the detailed description and the accompanying drawings, wherein:

FIG. 1 illustrates a related art global charge balance (GCB) edge termination structure;

FIG. 2 illustrates a related art local charge balance (LCB) edge termination structure;

FIG. 3 illustrates a first non-limiting example of an edge termination structure in accordance with at least one exemplary embodiment;

FIG. 4 illustrates a second non-limiting example of an edge termination structure in accordance with at least one exemplary embodiment;

FIG. 5 illustrates a third non-limiting example of an edge termination structure in accordance with at least one exemplary embodiment;

FIG. 6 illustrates a fourth non-limiting example of an edge termination structure in accordance with at least one exemplary embodiment;

FIG. 7 illustrates a fifth non-limiting example of an edge termination structure in accordance with at least one exemplary embodiment;

FIG. 8 illustrates a sixth non-limiting example of an edge termination structure in accordance with at least one exemplary embodiment;

FIG. 9 illustrates a seventh non-limiting example of an edge termination structure in accordance with at least one exemplary embodiment;

FIG. 10 illustrates an eighth non-limiting example of an edge termination structure in accordance with at least one exemplary embodiment;

FIG. 11 illustrates a ninth non-limiting example of an edge termination structure in accordance with at least one exemplary embodiment;

FIG. 12 illustrates a tenth non-limiting example of an edge termination structure in accordance with at least one exemplary embodiment;

FIG. 13 illustrates an eleventh non-limiting example of an edge termination structure in accordance with at least one exemplary embodiment;

FIGS. 14-19 illustrate a non-limiting method of fabrication of an edge termination structure in accordance with at least one exemplary embodiment; and

FIG. 20 illustrates an enlarged plan view of a portion of at least one exemplary embodiment of a semiconductor device that is formed on a semiconductor die.

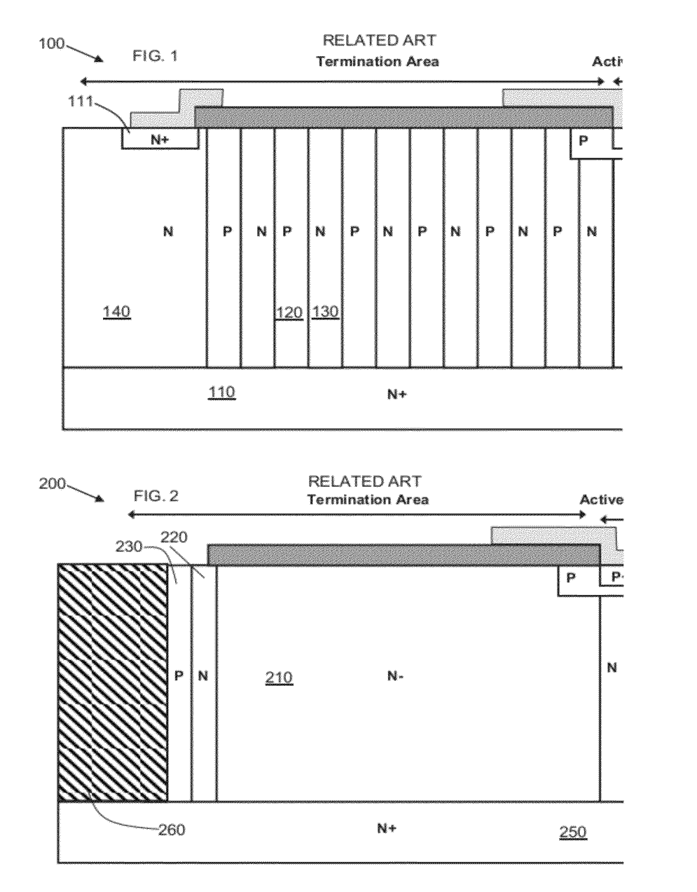

### DETAILED DESCRIPTION OF EXEMPLARY EMBODIMENTS

The following description of exemplary embodiment(s) is merely illustrative in nature and is in no way intended to limit the invention, its application, or uses.

For simplicity and clarity of the illustration(s), elements in the figures are not necessarily to scale, are only schematic and are non-limiting, and the same reference numbers in different figures denote the same elements, unless stated otherwise. Additionally, descriptions and details of well-known steps and elements are omitted for simplicity of the description. As used herein current carrying electrode means an element of a device that carries current through the device such as a source or a drain of a MOS transistor or an emitter or a collector of a bipolar transistor or a cathode or anode of a diode, and a control electrode means an element of the device that controls current flow through the device such as a gate of a MOS transistor or a base of a bipolar transistor. Although the devices may be explained herein as certain N-channel or P-Channel devices, or certain N-type or P-type doped regions, a person of ordinary skill in the art will appreciate that complementary devices are also possible. Note that although the term pillar is often used in the description the term is general for example a pillar can refer to a layer seen in a cross-sectional view.

It will be appreciated by those skilled in the art that the words “during”, “while”, and “when” as used herein relating to circuit operation are not exact terms that mean an action takes place instantly upon an initiating action but that there may be some small but reasonable delay, such as a propagation delay, between the reaction that is initiated by the initial action. Additionally, the term “while” means that a certain action occurs at least within some portion of a duration of the initiating action. The use of the word “approximately” or “substantially” means that a value of an element has a parameter that is expected to be close to a stated value or position. However, as is well known in the art there are always minor variances that prevent the values or positions from being exactly as stated. It is well established in the art that variances of up to at least ten percent (10%) (and up to twenty percent (20%) for semiconductor doping concentrations) are reasonable variances from the ideal goal of exactly as described.

The terms “first”, “second”, “third” and the like in the Claims or/and in the Detailed Description are used for distinguishing between similar elements and not necessarily for describing a sequence, either temporally, spatially, in ranking or in any other manner. It is to be understood that the terms so used are interchangeable under appropriate circumstances and that the exemplary embodiments described herein are capable of operation in other sequences than described or illustrated herein. For clarity of the drawings, doped regions of device structures are illustrated as having generally straight line edges and precise angular corners. However, those skilled in the art understand that due to the diffusion and activation of dopants the edges of doped regions generally may not be straight lines and the corners may not be precise angles.

In addition, the description may illustrate a cellular design (where the body regions are a plurality of cellular regions) instead of a single body design (where the body region is comprised of a single region formed in an elongated pattern, typically in a serpentine pattern). However, it is intended that the description is applicable to both a cellular implementation and a single base implementation.

Notice that similar reference numerals and letters refer to similar items in the following figures, and thus once an item is defined in one figure, it may not be discussed or further defined in the following figures.

Processes, techniques, apparatus, and materials as known by one of ordinary skill in the art may not be discussed in detail but are intended to be part of the enabling description where appropriate. For example specific methods of semiconductor doping or etching may not be listed for achieving each of the steps discussed; however one of ordinary skill would be able, without undo experimentation, to establish the steps using the enabling disclosure herein.

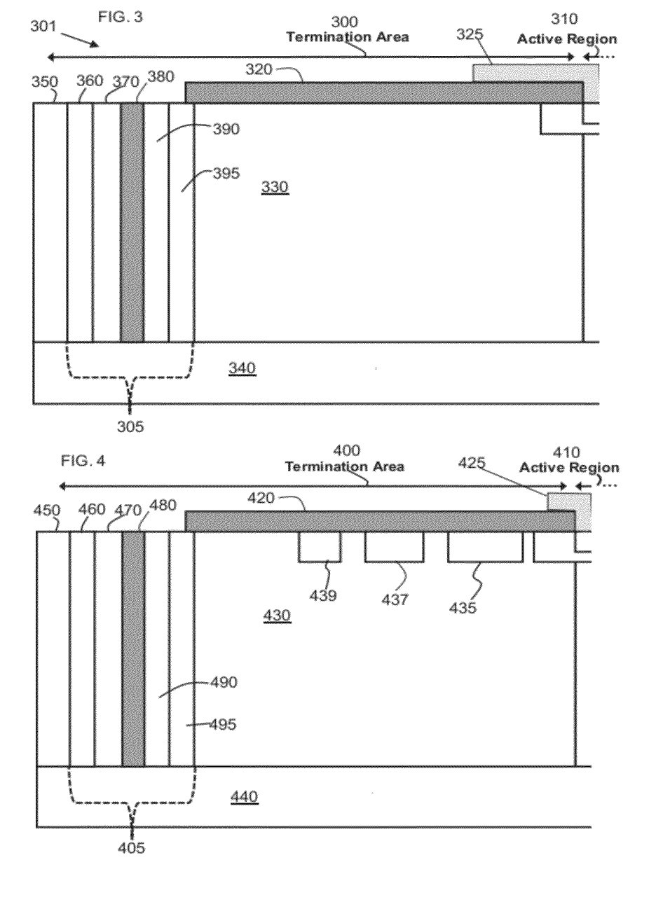

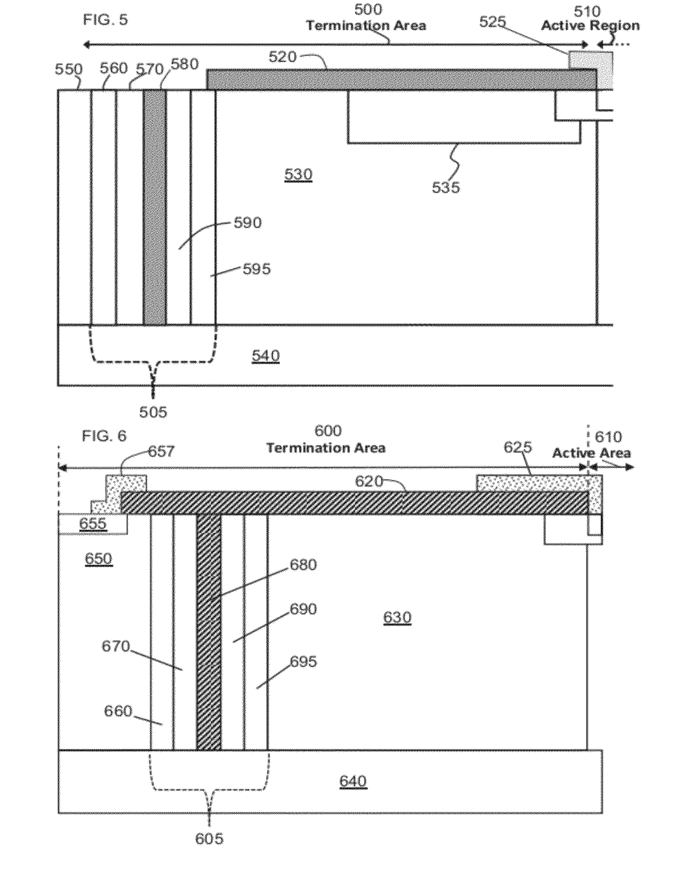

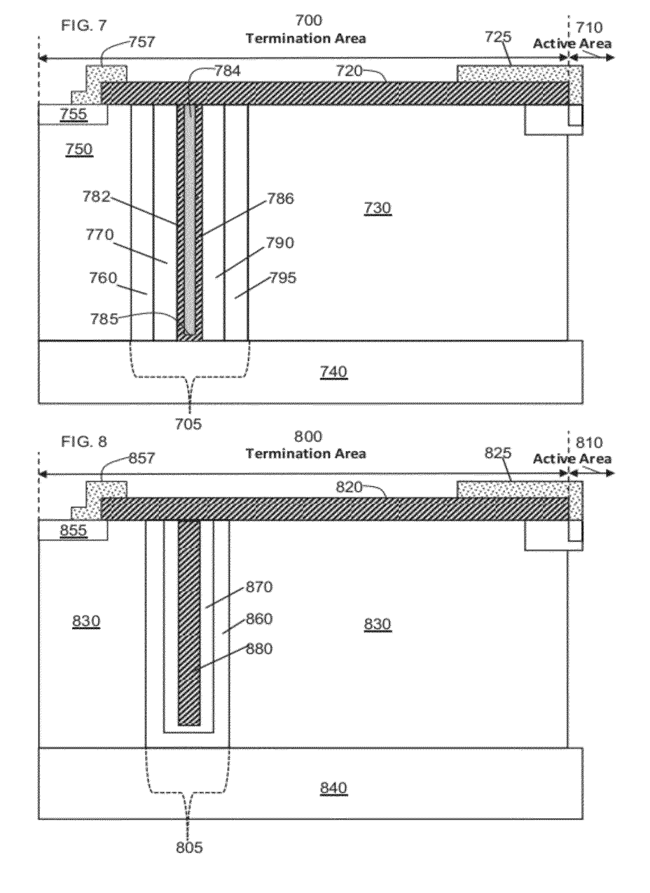

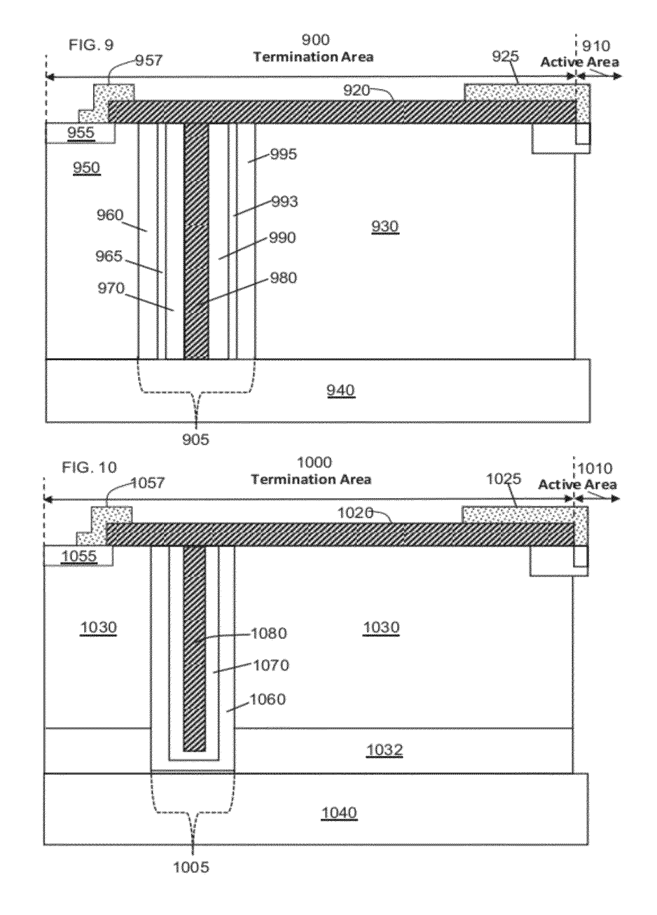

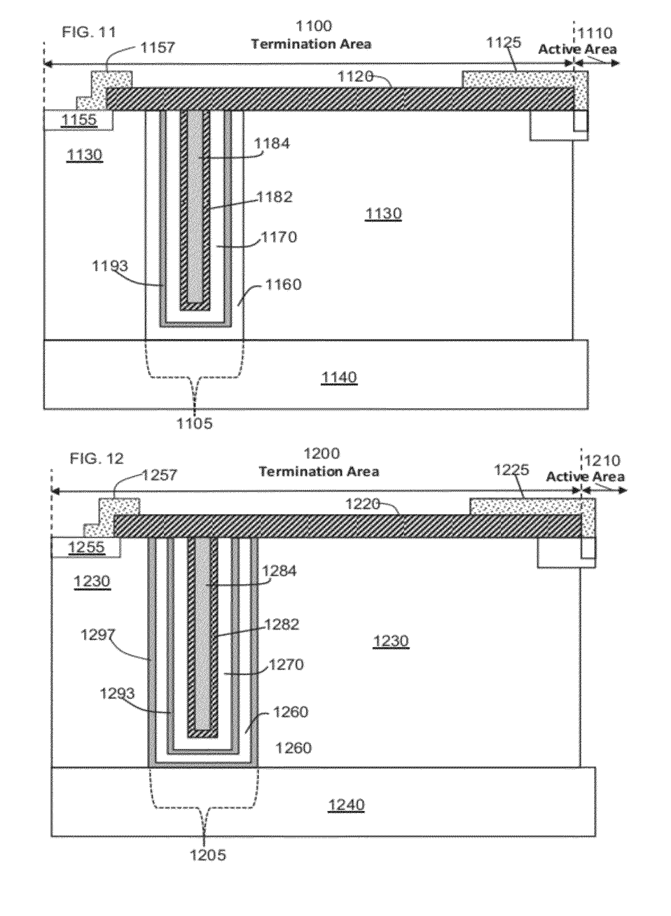

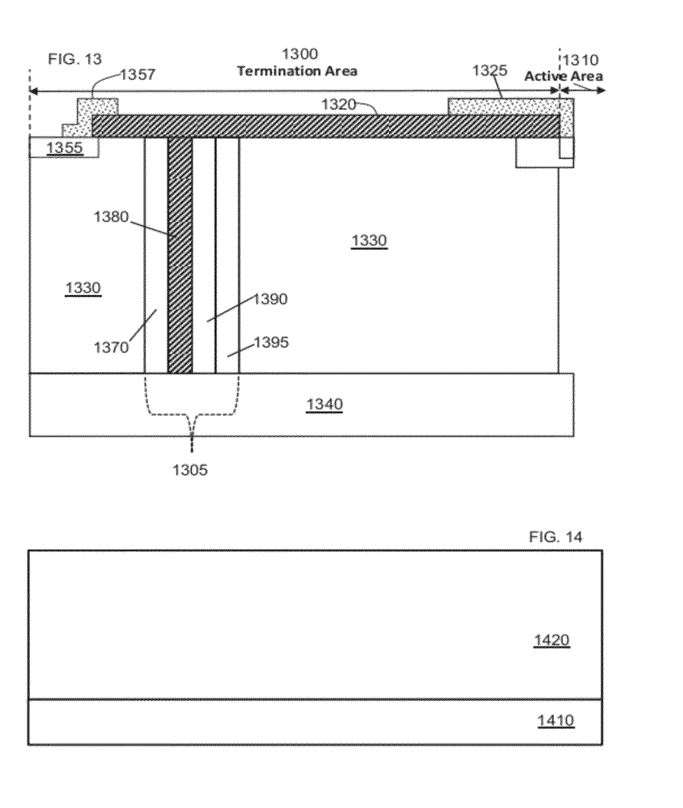

Although discrete layers are discussed with reference to several exemplary embodiments and FIGs (e.g., FIG. 3, FIG. 4, FIG. 5, FIG. 6, FIG. 7, FIG. 9, FIG. 13), at least one exemplary embodiment is directed to an edge termination structure formed in a trench etched in a semiconductor layer (e.g., FIG. 8, FIG. 10, FIG. 11, FIG. 12). Thus in accordance with at least one exemplary embodiment at least one semiconductor device can include filled trenches, semiconductor material filled trenches, epitaxial filled regions or trenches, charge compensating trench regions, deep trench charge compensation regions, and charge compensating filled trenches. The trenches can include a plurality of layers or multiple layers of semiconductor material, including layers of opposite conductivity type, which are preferably separated by separator layer or a buffer region. The buffer layer functions, among other things, to prevent intermixing of the opposite conductivity type layers (i.e., the two charge layers), which would negatively impact the conduction efficiency of a semiconductor device in the on state. Additionally note that in the non-limiting discussions the termination area (e.g., 500) and the active region (e.g., 510) are separated, however in at least one exemplary embodiment the edge termination structure (e.g., 505) can be formed in the active region, and the discussion herein should not be interpreted to limit where the termination edge structure (e.g., 505) is formed.

At least one exemplary embodiment is directed to an edge termination structure that includes an NP-buffer-PN or NP-buffer-N pillar structure (e.g., FIG. 13). These pillar structures sustain a significant part of the lateral potential drop in the termination as well as reducing the potential lines extension to the edge of the die. The low doped epitaxy semiconductor layer can block part of the BV with the pillar structure blocking the rest of the BV, which stops the depletion front in the lateral direction. In at least one exemplary embodiment the NP-buffer-PN pillar structure in the edge termination structure is identical to the NP-buffer-PN pillar in the basic cell. The formation of a basic cell is described in U.S. Pat. No. 7,253,477 the disclosure of which is incorporated herein by reference in its entirety.

In at least one further exemplary embodiment the pillar structure of an edge termination structure in accordance with at least one exemplary embodiment can be combined with one of the conventional methods to reduce the electric field at the termination side of the last active cell. For example several methods include: (a) field plate, (b) floating p-rings and (c) junction termination extension (JTE). Additionally at least one exemplary embodiment of an edge termination structure can be combined with any semiconductor device, for example IGBTs, Junction-Schottky diodes, and Thyristors.

At least one exemplary embodiment exhibited, with an imposed voltage of about 700V, a termination length below 100 μm, without compromising the reliability of the device due to high electric fields at the die edge. Note that a comparable system using GCB termination in a power MOSFETS exhibited a termination length of about 200 μm.

FIG. 3 illustrates a semiconductor device 100, including an edge termination structure 305 in a termination area 300 in accordance with at least one exemplary embodiment. A semiconductor device 301 comprising an active region 310 and a termination area 300 is illustrated. The active region 310 includes a source electrode 325, contacting source active cells, which is in contact with a dielectric 320. An epitaxy region (e.g., semiconductor layer 330) is operatively attached to an edge termination structure which includes several pillars or layers formed vertically in the semiconductor region 330. The edge termination structure 305 can be various combinations of variously doped layers for example NP-dielectric-PN or NP-dielectric-N pillar structures.

The NP-buffer-PN, PN-buffer-NP, NP-buffer-N pillar structures facilitate depletion. The depletion front from the active region 310 reaches a first doped region 395 (e.g., a first N-pillar) at a given applied voltage (e.g., 200V). As the applied voltage is increased (e.g., from 200V to 800V) the depletion advances in the vertical direction while the lateral depletion of the first doped region 395 (e.g., first N-pillar) is slower. At a particular voltage (e.g., 800V) the first doped region 395 (e.g., first N-pillar) becomes depleted at the top and the depletion reaches a junction between the first doped region 395 and a second doped region 390 (e.g., a first P-pillar). The complete depletion of the first doped region 395 is extended from top to bottom (e.g., from a surface of the semiconductor layer 330 to a semiconductor substrate 340 such as an N+ substrate). When the first doped region 395 is depleting, the second doped region 390 can also be depleting.

A buffer region 380 (e.g., an insulator layer, an intrinsic layer, an oxide layer, a gas region, a dielectric layer, and a combination of layers and regions) can be positioned between the second doped region 390 and a third doped region 370 (e.g., a second P-pillar). During the process of depletion within the buffer region 380 the potential lines are accumulated into the buffer region 380. Depending upon the voltage applied the second doped region 390 (e.g., first P-pillar) can be partially depleted or completely depleted at BV. The dielectric layer between the second 390 and third 370 doped regions (e.g., between the first P-pillar and the second P-pillar) facilitates laterally confining the potential lines in the insulating layer 380 (e.g., dielectric pillar).

In at least one exemplary embodiment the third doped region is a P doped region 370 with an adjacent N-doped region 360. The N-doped region is adjacent to either another layer 350 which is doped differently from the semiconductor layer 330 or is an extension of the semiconductor layer 330 in which the edge termination structure 305 has been formed.

The depletion region (termination area 300) can be decreased in extent by having high doping concentration (e.g., N doped) of the third doping region, and thus facilitating a good electrical connection between the third doped region 370 and the semiconductor substrate 340 (e.g., N+ substrate). Thus at least one exemplary embodiment (for example illustrated in FIG. 3) is directed to an NP-buffer-PN or a PN-buffer-NP pillar edge termination structure (FIG. 3, 395-390-380-370-360), while at least another exemplary embodiment (e.g., FIG. 13) is directed to a NP-buffer-N pillar edge termination structure (FIG. 13, 1395-1390-1380-1370).

The effect of the potential drop into the dielectric pillar facilitates keeping the die edge safe from high electric fields. Additionally the edge termination structure partially sustains the voltage into the dielectric pillar thus avoiding a BV degradation. In at least one exemplary embodiment the edge termination structure is coupled with field plate, JTE and floating p-rings terminations. However JTE and floating p-rings terminations show a more optimum potential distribution than the field plate one. For a similar termination length the maximum BV for the JTE is larger than that for a field plate termination.

The first doped region 395 provides a low resistance current path for the active region 310. In at least one exemplary embodiment, the first doped region 395 can be an N-doped layer with a concentration on the order of about 6×10¹⁶ atoms/cm³. The second doped region 390 can be a P-doped layer, which provides better control of a PN junction between first doped region 395 and the second doped region 390, and provides charge compensation for the first doped region 395 under full depletion conditions. In at least one exemplary embodiment the second doped region 390 can be P doped with a concentration on the order of about 6.0×10¹⁶ atoms/cm³.

As discussed previously at least one exemplary embodiment is directed to a NP-dielectric-N pillar (e.g., as illustrated in FIG. 13). Note that although in the non-limiting examples discussed a first doped region 1395 can be referred to as a first N-doped region, in other exemplary embodiment the various region can be otherwise doped (e.g., P, N+, N−, P+). Thus instead of being referred to as N-pillar, P-pillar, dielectric layers, reference to the Figures for example FIG. 13 will be more general referring to doped regions. Such generality should be applied in interpreting the non-limiting examples discussed. FIG. 13 illustrates a non-limiting example of an edge termination structure in accordance with at least one exemplary embodiment. FIG. 13 illustrates a semiconductor device comprising: a semiconductor substrate 1340, a semiconductor layer 1330, an active region 1310, and an edge termination structure 1305.

The semiconductor substrate 1340 can be of a first conductivity type, for example an N+ doped conductive layer. A semiconductor layer 1330 of a second conductivity type (e.g., an epitaxial layer of N− doped) can be formed overlying the semiconductor substrate 1340. An active region 1310 can be formed in a portion of the semiconductor layer 1330. An edge termination structure 1305 can also be formed in a second portion of the semiconductor layer 1330. The edge termination structure 1305 facilitates depletion and the reduction of the electric field at the edge (left side of region 1330). The edge termination structure 1305 comprises: a first doped region 1395, a second doped region 1390, a buffer region 1380 (e.g., an insulator layer, an intrinsic layer, an oxide layer, a gas region, a dielectric layer, and a combination of layers and regions), and a third doped region 1370. The first doped region 1395 can be a third conductivity type (e.g., N-doped). The second doped region 1390 can be a fourth conductivity type (e.g., P-doped) formed adjacent to the first doped region 1395. A buffer region 1380 can lie between the second doped region 1390 and a third doped region 1370. The third doped region 1370 can be of a fourth conductivity type (e.g., N-doped). The first 1395, second 1390, third 1370 doped regions and the buffer region 1380 form an edge termination structure 1305.

The various doped regions can be of various thicknesses as needed. For example the first doped region 1395 can be an N-pillar which can have a thickness between about 0.1 and 10.0 microns, more particularly between about 0.2 and 2.0 microns. The second doped region 1390 can be a P-pillar which can have a thickness between about 0.1 and 10 microns, and more particularly between about 0.2 and 2.0 microns. The buffer region 1380 can be between about 0.1 and 10 microns, and more particularly between about 0.1 and 2.0 microns. Note that the buffer region 1380 can include several type of layers of dielectrics and insulators. For example the buffer region 1380 can include an oxide layer and a gas region.

The non-limiting example illustrated in FIG. 13, illustrates the use of four layers (pillars) in the edge termination structure 1305. However exemplary embodiments can have numerous layers (pillars) and are not restricted to any particular number. For example FIGS. 3, 4, 5, and 6 illustrate an edge termination structure 305 (e.g., 405, 505, and 605) that has five layers (pillars), 395, 390, 380, 370, and 360. The first doped region 395 (e.g., 495, 595, 695) can be N-doped, the second doped region 390 (e.g., 490, 590, 690) can be P doped, the buffer region 380 (e.g., 480, 580, 680) can be a dielectric or intrinsic layer, the third doped region 370 (e.g., 470, 570, 670) can be P doped and the fourth doped region 360 (e.g., 460, 560, 660) can be N doped, forming a NP-dielectric-PN edge termination structure 305 (e.g., 405, 505, 605). Note that the actually conductivity type (P doped, N doped, N− doped, N+ doped) can vary and discussion herein are non-limiting examples, thus for example the first doped region (e.g., 395, 495, 595, 695) can be P-doped.

As previously mentioned the edge termination structure of exemplary embodiments can be used with ring and plate systems. FIG. 4 and FIG. 5 illustrate the incorporation of P-ring structures in the semiconductor layer 430 (FIG. 4) and semiconductor layer 530 (FIG. 5). FIG. 4 illustrates multiple P-ring structures (e.g., 439, 437, 435), while FIG. 5 illustrates one P-ring structure (e.g., 535). Additionally FIGS. 3-13 illustrate the optional use of a dielectric plate (e.g., 320, 420, 520, 620, 720, 820, 920, 1020, 1120, 1220 and 1320), operationally connected to the respective active regions (e.g., 310, 410, 510, 610, 710, 810, 910, 1010, 1110, 1210, and 1310) via a conductive source electrodes (e.g., 325, 425, 525, 625, 725, 825, 925, 1025, 1125, 1225, and 1325). The dielectric plates can optionally be operationally connected to the edge of the semiconductor layer via N+ contact regions (e.g., 655,755, 855, 955, 1055, 1155, 1255, and 1355) where the N+ contact regions are coupled to the plate via edge electrodes (e.g., 657, 757, 857, 957, 1057, 1157, 1257, and 1357). Note that the edge of the semiconductor device can include a layer (e.g., 350, 450, and 550) that need not be the same as the respective semiconductor layer (e.g., 330, 430, and 530). Additionally the layers 350, 450, and 550 can also be a part of the semiconductor layer 330, 430 and 530 respectively, in which the edge termination structure was formed. Note that the contact regions (e.g., 655) can extend to the doped region closest to the contact region (e.g., 660) and to other doped regions beyond (e.g., 670, 680).

In at least one exemplary embodiment the vertical structure of the edge termination structure (e.g., 305, 405, 605, 705, 805, 905, 1105, 1205, and 1305) can be of various extent, for example the vertical extent of the edge termination structure can reach to the semiconductor substrate layer (e.g., 340, 440, 540, 640, 740, 840, 940, 1140, 1240, and 1340). Additionally at least one exemplary embodiment has an edge termination structure whose vertical extent does not penetrate to the semiconductor substrate. For example FIG. 10 illustrates an edge termination structure 1005, whose vertical extent terminates in a buffer layer 1032. The buffer layer 1032 has a doping concentration between the semiconductor layer 1030 and the semiconductor substrate 1040. The buffer layer can be a thin layer between 1 and 100 microns thick, predominately between about 5 and 25 microns thick.

The buffer region (e.g., 380, 480, 580, 680, 880, 980, 1080, and 1380) can include multiple layers of dielectrics, intrinsic layers, and gas. For example FIG. 7 illustrates a buffer region which includes a dielectric layer 782, a gas region 784, and another dielectric layer 786. Note that the dielectric layers 782 and 786 can be formed from a single dielectric layer in which case the layers will be joined 785 at the bottom of the edge termination structure. The dielectric layers, 782, 785, and 786 can be oxide layers, intrinsic semiconductor layers, or other insulators as known by one of ordinary skill in the semiconductor device art. As illustrated in FIG. 7 the gas region 784 can be substantially enclosed by the three dielectric layers 782, 785, and 786. The gas can be a vacuum, air, or other gas (including out gassing from the layers themselves). The dielectric layers 782, 785, and 786 can have a thickness of about 10 nanometers to 5 microns, and more particularly between about 50 nanometers and 1 micron. The gas region can have a thickness of about 0.1 to 10 microns, and more particularly between about 0.2 and 2.0 microns.

Just as the dielectric layers in a buffer region can be formed by a single layer deposited in a trench, so to can the various doped regions forming the layers (pillars) of the edge termination structure also be formed by individual layers deposited in a trench. For example FIG. 8 illustrates an edge termination structure 805 where the first and fourth doped regions are formed by depositing a first doped layer 860 in a trench. For example the first doped layer can be P-doped. A second doped layer can be deposited in the remaining trench adjacent to the first doped layer. For example the second doped layer can be N-doped. Then an insulator layer 880 can be deposited in the remaining trench forming the edge termination structure 805. FIGS. 10, 11, and 12 additionally illustrate trench filled edge termination structures. FIG. 10 illustrates a similar edge termination structure as illustrated in FIG. 8, where the vertical extent of the edge termination structure 1005 terminates in a buffer layer 1032. Note that the vertical extent of the various edge termination structures can vary, for example between about 0.1 and 10 microns.

In at least one exemplary embodiment the doped regions are separated by intrinsic layers. For example FIG. 9 illustrates a first dope region 995 separated from a second doped region 990 by a first separator layer 993 (e.g., an intrinsic layer and/or a dielectric layer). Note that the separator layer can have variable thickness, for example between about 10 nanometers and 1 micron. Additionally the edge termination structure can have multiple separator layers, for example the third doped region 970 can be separated from the fourth doped region 960 by a second separator layer 965. Alternatively as discussed previously when edge termination structures are formed in trenches, the first and second separator layer can be a single layer deposited after the deposition of the first doped region 995. A separator layer functions, among other things, to prevent the mixing of layers various doped regions, which improves the conduction efficiency of the edge termination structure 905.

In at least one exemplary embodiment of an edge termination structure can be formed by filled trenches or discrete layers and can include multiple layers or stacked layers of semiconductor material formed using epitaxial growth techniques. FIGS. 11 and 12 illustrate trenched filled edge termination structures 1105 and 1205 respectively. The edge termination structure 1205 illustrated in FIG. 12 includes two separator layers 1297 and 1293. For example a first doped region 1160 can be formed on, over, or adjoining the trench walls forms in the semiconductor layer 1130. A separator layer 1193 can be is formed on, over or adjoining the first doped region 1160. Then the second doped region 1170 can be formed on, over or adjoining the separator layer 1193. The buffer region can be a combination of a dielectric layer 1182 and a gas region 1184 (a gap). The dielectric 1182 can be formed on, over, or adjoining the second doped region 1170. The resulting edge termination structure 1105 can vary in extent vertically depending upon the initial trench depth and the thickness of the deposited layers. Note that layers 1193, 1293, and 1297 can be intrinsic layers, insulation layers, and dielectric layers and the discussion herein should not be interpreted to limit the material the layers are made of or their material properties.

Although non-limiting examples are discussed with single NP-buffer-PN structures additional layers (e.g., variously N-doped and P-doped) can be used, and the additional layers can be optionally separated by separator layers. For example FIG. 12 illustrates an edge termination structure 1205 which includes a first separator layer 1297, a first doped region 1260, a second separator layer 1293, a second doped region 1270, an oxide region 1282 substantially encompassing a gas region 1284. Note that the gas region can also be filled with the oxide and thus the oxide region 1282 and the gas region 1284 would be a single buffer region.

Note that the doped levels (conductivity type) in exemplary embodiments can vary. For a non-limiting example N-doped and P-doped regions can have concentrations on the order of about 1×10¹³ to about 1×10¹⁸ atoms/cm³, and more particularly concentrations on the order of 1×10¹⁵ to about 1×10¹⁷ atoms/cm³. Intrinsic layers are undoped or lightly doped regions (e.g., P-doped) with a dopant concentrations less than about 2×10¹⁴ atoms/cm³. Additionally the intrinsic layer thickness can vary for example between about 50 nanometer and about 2 microns.

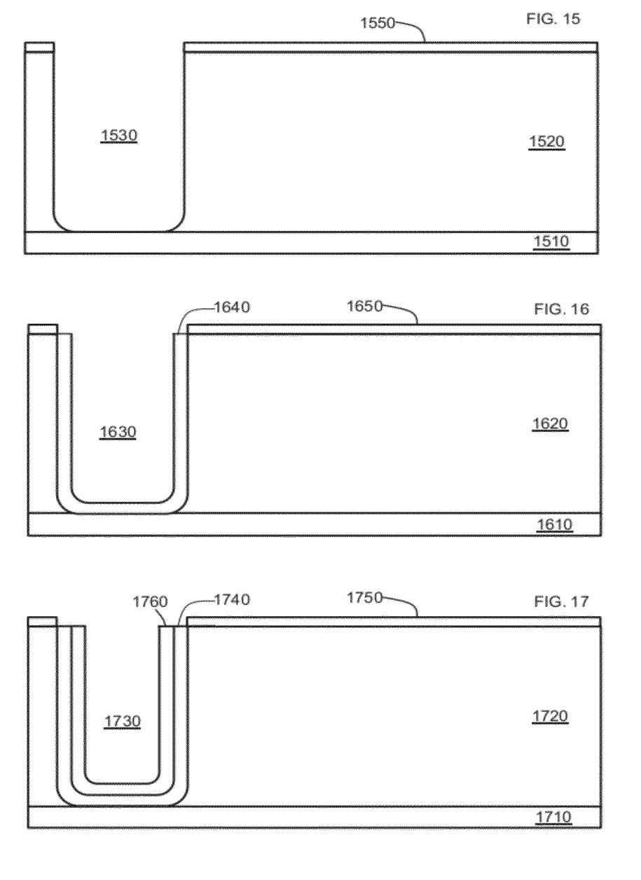

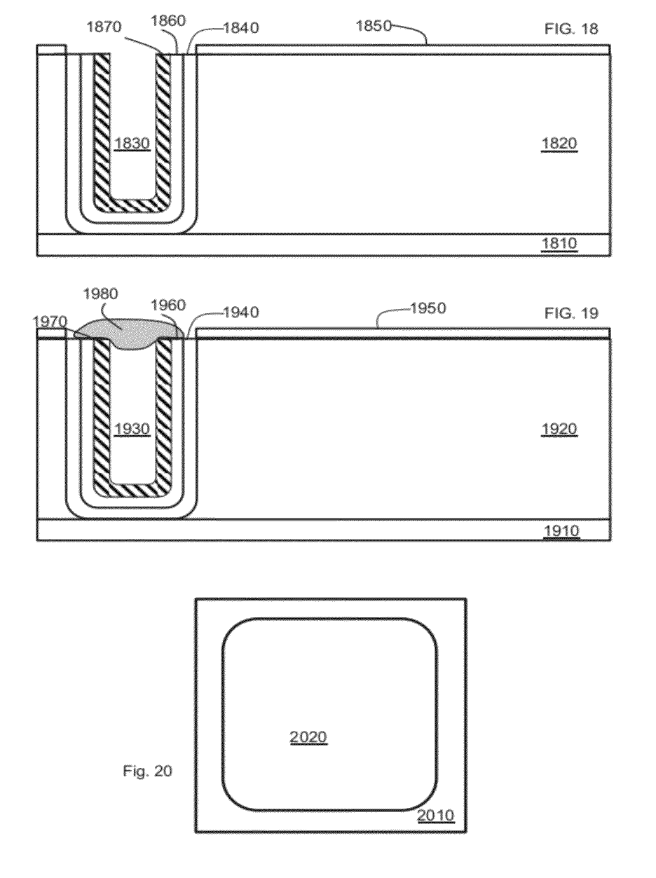

FIGS. 14-19 illustrate the process of formation of an edge termination structure in accordance with at least one exemplary embodiment. A doped semiconductor layer 1420 (e.g. N− doped epitaxy layer) can be formed on a doped (e.g., N+ doped) semiconductor substrate 1410 (FIG. 14). An additional dielectric layer 1550 (e.g., 1650, 1750, 1850, and 1950) can be deposited onto the surface of the semiconductor layer 1520 (e.g., 1620, 1720, 1820, and 1920). A first recess 1530 (e.g., a first trench) can be etched into the semiconductor layer 1520 and dielectric layer 1550 using know semiconductor etching techniques (e.g., DRIE etching). The vertical extent of the trench can reach the semiconductor substrate 1510 or the semiconductor layer 1520 or into a buffer region (not shown). A first doped layer (first doped region) 1640 can be formed on, over, or adjoining the surface of the first recess 1530, forming a second recess 1630 in the semiconductor layer 1620. Note that prior to the first doped region a separator layer (not shown) can be formed to separate the first doped layer 1640 from the semiconductor layer 1620. A second doped layer 1760 can be formed on, over, or adjoining the surface of the first doped layer 1740 forming a third recess 1730 in the semiconductor layer 1720. Additionally a second separator layer (not shown) can be formed on the first doped layer 1740 prior to forming the second doped layer 1760 to separate the first dope layer 1740 from the second doped layer 1760. A buffer region 1870 (e.g. dielectric layer, oxide layer, insulator layer, gas region, an intrinsic layer and/or a combination of such layers and regions) can be formed on, over, or adjoining the surface of the second doped layer 1860 forming a fourth recess 1830 in the semiconductor layer 1820. The fourth recess 1830 can be a gas region or filled. The fourth recess 1830 can be capped 1980 forming a fifth recess region 1930. The resultant structure is an edge termination structure including a first doped region 1940, a second doped region 1960, a dielectric layer 1970, and a gas region 1930.

FIG. 20 illustrates an enlarged plan view of a portion of an embodiment of a semiconductor device 2020 that is formed on a semiconductor die 2010. Die 2010 may also include other circuits that are not shown in FIG. 20 for simplicity of the drawing. Device 2020 is formed on die 2010 by semiconductor manufacturing techniques that are well known to those skilled in the art.

While the present invention has been described with reference to exemplary embodiments, it is to be understood that the invention is not limited to the disclosed exemplary embodiments. The scope of the following claims is to be accorded the broadest interpretation so as to encompass all modifications, equivalent structures and functions. For example, if words such as “orthogonal”, “perpendicular” are used the intended meaning is “substantially orthogonal” and “substantially perpendicular” respectively. Additionally although specific numbers may be quoted in the claims, it is intended that a number close to the one stated is also within the intended scope, i.e. any stated number (e.g., 90 degrees) should be interpreted to be “about” the value of the stated number (e.g., about 90 degrees).

In view of the above, it is evident that a novel device and method is disclosed that can, in at least one exemplary embodiment, have a reduced termination area while minimizing E-field line termination at the edge of the die edge, additionally providing lower RS, and a high BV.

As the claims hereinafter reflect, inventive aspects may lie in less than all features of a single foregoing disclosed embodiment. Thus, the hereinafter expressed claims are hereby expressly incorporated into this Detailed Description of a non-limiting sample of exemplary embodiments, with each claim standing on its own as a separate embodiment of an invention. Furthermore, while some exemplary embodiments described herein include some but not other features included in other embodiments, combinations of features of different embodiments are meant to be within the scope of the invention, and form different embodiments, as would be understood by those skilled in the art.

Thus, the description of the invention is merely exemplary in nature and, thus, variations that do not depart from the gist of the invention are intended to be within the scope of the exemplary embodiments of the present invention. Such variations are not to be regarded as a departure from the spirit and scope of the present invention.

What is claimed is:

1. A semiconductor device comprising:
a semiconductor substrate of a first conductivity type having an edge portion;
a semiconductor layer of a second conductivity type formed overlying the semiconductor substrate;
an active region formed in a portion of the semiconductor layer; and
an edge termination structure, where the edge termination structure comprises:
a first doped region of a third conductivity type;
a second doped region of a fourth conductivity type formed adjacent to the first doped region;
a first buffer region formed adjacent to the second doped region; and
a third doped region of the fifth conductivity type formed adjacent to the first buffer region.

2. The semiconductor device according to claim 1, where the third conductivity type is N, where the first doped region is an N doped region, where the fourth conductivity type is P, where the second doped region is a P doped region, and where the fifth conductivity type is N, where the third doped region is an N doped region.

3. The semiconductor device according to claim 1 where the end termination structure further comprises:
a fourth doped region of a sixth conductivity type formed adjacent to the third doped region.

4. The semiconductor device according to claim 3, where the third conductivity type is N, where the first doped region is an N doped region, where the fourth conductivity type is P, where the second doped region is a P doped region, and where the fifth conductivity type is P, where the third doped region is a P doped region, and where the sixth conductivity type is N, where the fourth doped region if an N doped region.

5. The semiconductor device according to claim 3, where the first buffer region comprises:
at least one of a first oxide layer, a gas region, and an insulator.

6. The semiconductor device according to claim 5, where the first oxide layer is deposited so that the first oxide layer substantially encircles a gas region.

7. The semiconductor device according to claim 6, where the gas region is air.

8. The semiconductor device according to claim 3, where the first doped region and the fourth doped region form a first single layer.

9. The semiconductor device according to claim 8, where the second doped region and the third doped region form a second single layer.

10. The semiconductor device according to claim 3, further comprising:
a first buffer layer, where the first buffer layer lies between the semiconductor layer and the semiconductor substrate.

11. The semiconductor device according to claim 3 further comprising:
a first separator layer, where the first separator layer lies between the first doped region and the second doped region, and where the first separator layer is at least one of an intrinsic layer and a dielectric layer.

12. The semiconductor device according to claim 11 further comprising:
a second separator layer where the second separator layer lies between the third doped region and the fourth doped region, and where the second separator layer is at least one of an intrinsic layer and a dielectric layer.

13. The semiconductor device according to claim 12, where the first doped region and the fourth doped region form a first single layer, where the second doped region and the third doped region form a second single layer, where the first separator layer and the second separator layer form a third single layer.

14. The semiconductor device according to claim 13, further comprising:
a third separator layer, where the third separator layer lies between the first single layer and the semiconductor layer, and where the third separator layer is at least one of an intrinsic layer and a dielectric layer.

15. The semiconductor device according to claim 3, where the third conductivity type is P, where the first doped region is an P doped region, where the fourth conductivity type is N, where the second doped region is an N doped region, and where the fifth conductivity type is N, where the third doped region is a N doped region, and where the sixth conductivity type is P, where the fourth doped region if an P doped region.

16. A semiconductor edge termination structure comprising:
a first layer, where the first layer is formed from an N doped material and is formed in a trench, where at least one wall of the trench is formed in a semiconductor layer that is N− doped;
a separator layer, where the separator layer is adjacent to the first layer but is not adjacent to the substrate, and where the separator layer is at least one of an intrinsic layer and a dielectric layer;
a second layer, where the second layer is formed from a P doped material, were the second layer is adjacent to the separator layer but not the substrate, where the second layer is not adjacent to the first layer; and
a buffer region, where the buffer region is adjacent to the second layer.

17. The semiconductor edge termination structure according to claim 16, where the buffer region comprises:
a oxide layer; and
a gas layer, where the oxide layer substantially encompasses the gas layer so that the oxide layer is adjacent to the second layer while the gas layer is not adjacent to the second layer.

18. A method of forming a semiconductor edge termination structure comprising:
depositing a dielectric layer onto a semiconductor layer;
etching a first recess, where the first recess is etched into the dielectric layer and the semiconductor layer, where the semiconductor layer is doped to a first conductivity type;
depositing a first material into the first recess forming a second recess, where the first material has been doped to a second conductivity;
depositing a second material into the second recess forming a third recess, where the second material has been doped to a third conductivity; and
depositing a third material into the third recess forming a fourth recess, where the third material is a dielectric, where the first material, the second material, and the third material form an edge termination structure in the semiconductor layer, where the edge termination structure is configured to reduce an applied electric field from a first side of the termination structure to a second side of the termination structure.

19. The method according to claim 18, where the second conductivity type is N, and where the third conductivity type is P.

20. The method according to claim 19, where the termination structure is formed in a semiconductor device, where the semiconductor device is at least one of a JTE-based device, a Field-Plate-based device, a device using P+ rings, a IGBT, a Junction-Schottky diode, and a Thyristor.
